(19) United States
(12) Patent Application Publication
(10) Pub. No.: US 2012/0276804 A1
(43) Pub. Date: Nov. 1, 2012

(54) PHOTO-CUSTOMIZATION FOR FIGURINES

(76) Inventors: TAYLOR J. MCKENNA, Talent, OR (US); Susanna Jo Wood, Talent, OR (US)

(21) Appl. No.: 13/457,235

(22) Filed: Apr. 26, 2012

Related U.S. Application Data
(60) Provisional application No. 61/479,274, filed on Apr. 26, 2011.

(51) Int. Cl. A63H 3/16; G06K 9/46; G03F 7/00; B23P 11/00; B41F 17/00

(52) U.S. Cl. 446/100; 29/428; 156/58; 382/190

(57) ABSTRACT

Embodiments of the invention include providing a figurine, a film for application to a surface of the figurine, wherein the film is to receive an image from a digital photograph provided by a user, and wherein the figurine is customizable by applying the film with the image from the digital photograph provided by the user to the surface of the figurine.

### PRIORITY

The present application is a Non-Provisional of, and claims priority to and incorporates by reference, the corresponding U.S. Provisional Patent Application No. 61/479,274 filed Apr. 26, 2011.

### TECHNICAL FIELD

Embodiments of the invention relate generally to customizable figurines. More particularly, embodiments of the invention relate to photo-personalized figurines (e.g., toy figurines).

### BACKGROUND

Children engaged in play enjoy imagining that they are different characters or performing different roles. For example, a child playing with a figurine of a doctor may pretend that the doctor figurine represents him or her and that he or she is a doctor. Such figurines may have components which can be arranged in different configurations (e.g., Lego™ brick persons with brick heads), but there are limits to the customizability of such figurines.

### BRIEF DESCRIPTION OF THE DRAWINGS

Non-limiting and non-exhaustive embodiments of the invention are described with reference to the following figures, wherein like reference numerals refer to like parts throughout the various views unless otherwise specified. It should be appreciated that the following figures may not be drawn to scale.

FIG. 1 is an illustration of photo-customization of a figurine according to one embodiment of the invention.

FIG. 2 is an illustration of customizing a figurine based on a digital photograph provided by a user according to one embodiment of the invention.

FIG. 3 is an illustration of a customizable figurine according to one embodiment of the invention.

FIG. 4 is a flow diagram of a method of providing a customizable figurine according to one embodiment of the invention.

FIG. 5 is a flow diagram of a method including generating an image from a received digital photograph according to one embodiment of the invention.

FIG. 6 is a block diagram of a machine in the exemplary form of a computer system according to one embodiment of the invention.

Descriptions of certain details and implementations follow, including a description of the figures, which may depict some or all of the embodiments described below, as well as discussing other potential embodiments or implementations of the inventive concepts presented herein. A more detailed description with reference to the drawings is provided below.

### DETAILED DESCRIPTION

Embodiments of photo-customization for a figurine are described herein. According to one embodiment of the invention, a figurine (a model of a form) can be personalized with a photograph (e.g., a face from a photograph). For example, a figurine head may be personalized with a face from a photograph (e.g., a child's facial features). In such an example, the face-personalized figurine head can then be attached to a figurine body (e.g., a toy brick-bodied figure). According to one embodiment, the photo-customization may have the benefit of providing customizable toys and allowing children to put themselves into the middle of their imaginative play for an immersive and enriching play experience. Photo-customization may be used for a wide variety of figurines (e.g., trophies, figures used for reenactments, roleplaying, planning, etc.).

In the following description numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

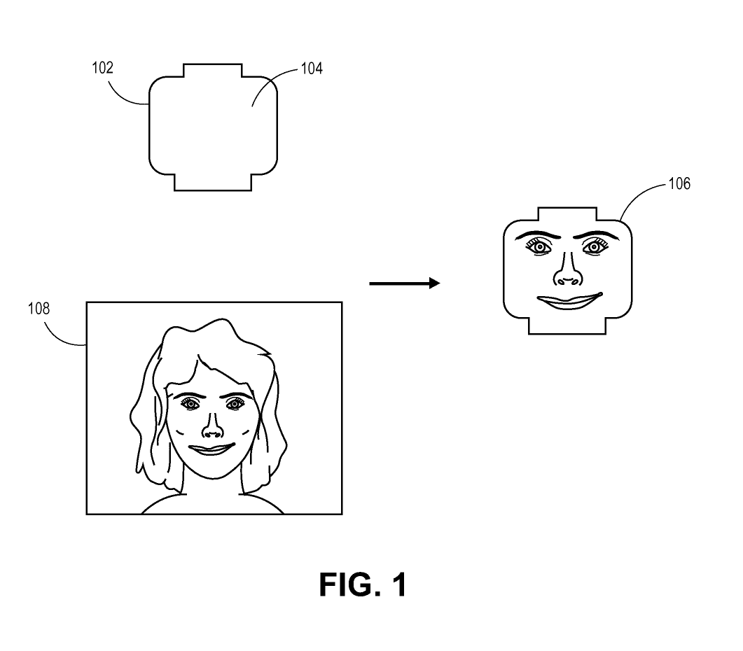

FIG. 1 is an illustration of photo-customization of a figurine according to one embodiment of the invention. According to this embodiment, a face from a digital photograph 108 (e.g., a close-up, high resolution face shot) provided by a user is applied to a figurine 102, which is shown here as a model of a head (e.g., a Lego™ toy brick head). In one such embodiment, the figurine 102 has an area 104 for applying a customization (e.g., a custom face based on a photograph). The surface 104 for application of a customization may be a variety of shapes, textures, and/or configurations.

According to one embodiment of the invention, a user can submit the photograph 108 to a service provider and receive a film for application to the figurine 102, or receive the personalized figurine 106. In another embodiment, a user can employ a means for generating an image from the photograph to personalize a figurine (e.g., a web application, or other software on a computing device, smart phone, etc.). In one such embodiment, a web application or software may provide additional functionalities for further customization (e.g., adding or deleting a feature from the photograph such as text, accessories, editing colors, modifying attributes of the photograph, etc.). Such additional customizations may be manual and/or automatic (e.g., a “surgeon” option for auto-adding a surgeon's cap or a “beach” option for auto-adding sunglasses).

In one embodiment, a method of providing a customizable figurine includes a figurine 102 having an area 104 (e.g., surface) to receive an image to personalize the figurine 102, a means for generating the image to personalize the figurine 102 from a digital image 108 provided by a user and sized for application to the surface of the figurine; and a means for applying the image to personalize the figurine to the surface 104 of the figurine. For example, a photo-personalization kit may include a customizable figurine and/or figurine part, a software means of generating an image to personalize the figurine from a user-provided digital image, and a means to apply the image to personalize the figurine (e.g., a sticky-back of a film, an adhesive, a snapping mechanism, a locking mechanism, etc.).

In another embodiment, the user may use a device to capture and/or receive digital photograph 108 and/or print a film for personalizing the figurine 102 or to directly apply a personalizing image onto the figurine 102. For example, a photo-personalizing device may be used by a user to perform some or all operations for personalizing a figure described herein.

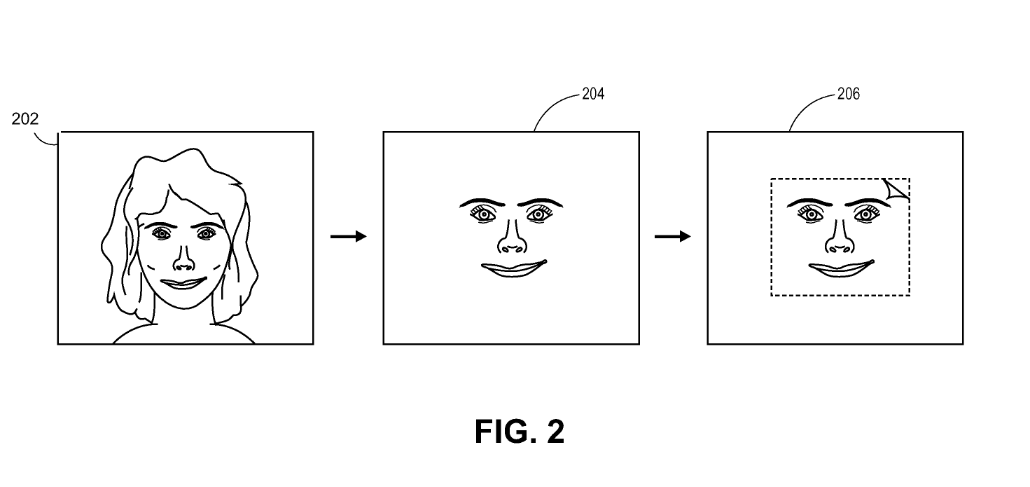

FIG. 2 is an illustration of customizing a figurine based on a digital photograph provided by a user according to one embodiment of the invention.

According to one embodiment, a photograph 202 is provided by a user. Providing a photograph 202 by a user may involve capturing the photograph with an image capture device (e.g., camera, mobile device, webcam, video recorder, etc.), and/or uploading, downloading, or accessing a previously captured photograph (e.g., via the internet, a cable, wireless protocol, etc. to a local or remote computing device). Photograph 202 may be of any ratio, resolution, or size, and/or have been modified subsequent to capture.

In one embodiment, photograph 202 is downloaded onto a computer from which image 204 is generated. Generating image 204 may involve desaturating a photograph 202 (e.g., making a color photograph black and white and/or monochromatic), contrasting features in photograph 202 (e.g., darkening a facial feature), and/or erasing background features in photograph 202 (e.g., eliminating hair, skin details, etc.). In another embodiment, instead of (or in addition to) erasing background features in photograph 202, some features are extracted from the photograph 202 to generate image 204 for use in customizing a figurine. According to one embodiment, a facial feature is extracted from photograph 202, but in other embodiments, other features may be extracted to personalize a figurine (e.g., a hair color or style, a facial expression, clothing or a uniform, etc.).

In one embodiment, generating the image 204 involves electronically stretching the photograph 202 (e.g., in order to adhere to and/or cover a curved surface of a figurine), or modify the photograph 202 in other ways for application to a variety of shapes, textures, and/or configurations of figurines. Such electronic stretching or other modification as applied to film may be done so as to not distort the feature from the photograph (e.g., a child's face).

According to one embodiment, generating image 204 also includes sizing the image from photograph 202 to fit on a figurine (e.g., for a Lego™ toy brick head, by adjusting the height to be equal to or less than approximately 0.205 inches), adjusting an aspect ratio, and/or by adjusting the dots-per-inch (e.g., increasing the dots-per-inch to, for example, 2900 dpi).

As described above, generating image 204 may be performed, for example, via a website application and/or remote service, on a computing device local to a user (e.g., using software installed on the local computing device such as Photoshop creative suite software, or proprietary software provided by a toy manufacturer), or via remote computing device (e.g., via equipment operated by a figurine manufacturer).

According to one embodiment, image 204 is printed onto a film 206 (e.g., onto a sticker with an adhesive side for adhering to the surface of the figurine, photo transparency medium, etc.) For example, image 204 is printed onto a 8/32″ thin strip of sticky-backed drafting film for application to a Lego™ brick head, according to one embodiment. Film 206 may be any medium capable of receiving image 204 and application to a figurine. In another embodiment, image 204 is applied to a figurine via another method (e.g., embossing, decal, printed directly onto the figurine, etc.) or to another material or item for customizing the figurine. In one embodiment using a sticky-backed film, a top section (e.g., a transparent top section) of the film 204 is removed from its backing and applied to a figurine to personalize the figurine (e.g., by hand smoothing the film onto a toy brick head, applied by an automated machine, etc.). In one embodiment, a finish (e.g., Krylon™ Gloss Finish Coat Spray) may be applied to the customized figurine (e.g., to keep the image and/or film intact). In another embodiment, the film is removably applicable, enabling customization of multiple figurines or figurine parts by removing the film from one figurine for application to a different figurine.

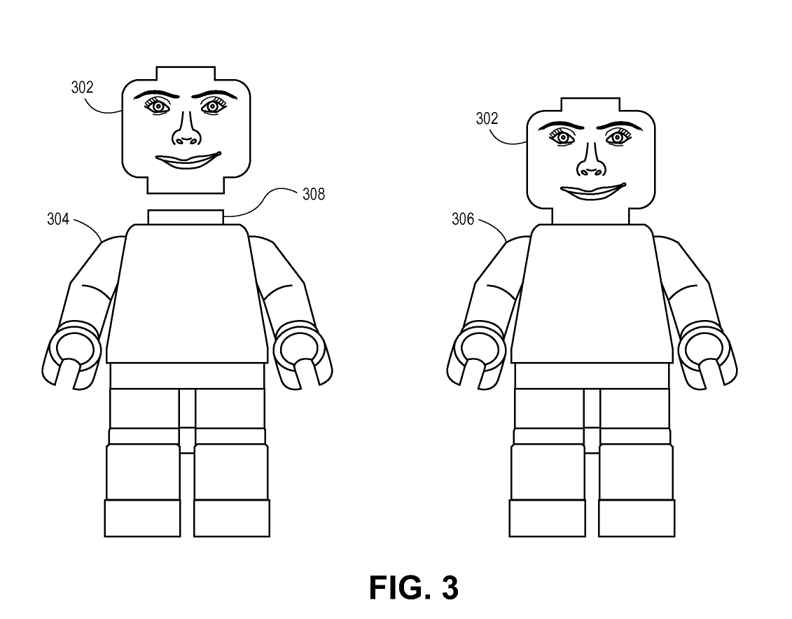

FIG. 3 is an illustration of a customizable figurine according to one embodiment of the invention. According to one embodiment, a figurine head 302 is personalized with a photograph provided by a user, and is removably attachable to figurine body 304. In one embodiment, personalized figurine head 302 is removably attachable (e.g., by inserting the figurine head 302 onto the round brick stud 308 of any compatible toy brick body) to a plurality of figurine bodies 304 and 306 for customizing a figurine. In one such embodiment, a figurine may be customized by the application of a film with an image from a user-provided photograph (e.g., a photograph of a child) to the figurine head 302, and attaching the figurine head 302 with the film applied to one of the plurality of figurine bodies 304 and 306. In one such embodiment, a user can personalize figurines real-time by putting the personalized head onto different figurine bodies (e.g., a pirate body, a doctor body, a lion body, a car, a robot, etc.). For example, a child can put personalized figurine head 302 onto a pirate body and pretend they are sailing the Seven Seas and moments later they can move it to a different toy body and become a doctor saving the lives of an entire village.

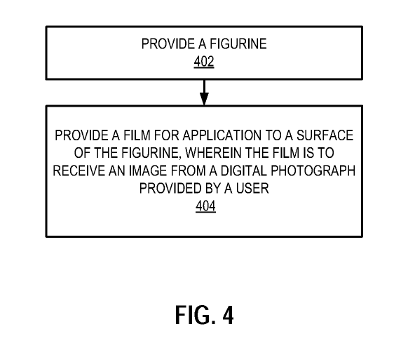

FIG. 4 is a flow diagram of a method of providing a customizable figurine according to one embodiment of the invention.

At block 402, a customizable figurine is provided (e.g., the figurine 102 in FIG. 1 or the figurine head 302 and body 304 in FIG. 3).

At block 404, a film (e.g., film 206 in FIG. 2) is provided for application to a surface of the figurine, wherein the film is to receive an image (e.g., image 204 in FIG. 2) from a digital photograph provided by a user. In one embodiment, a plurality of films are provided (e.g., additional and/or replacement films). According to one embodiment, the provided figurine is customizable by applying the provided film with the image from the digital photograph to the surface of the figurine.

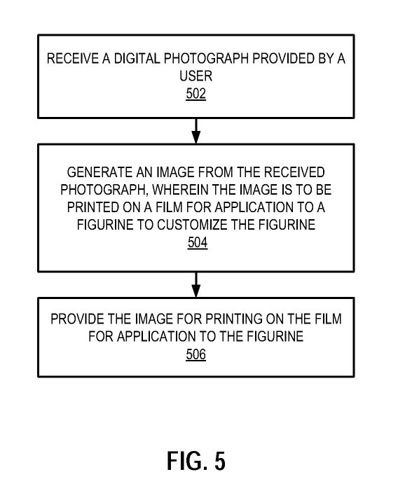

FIG. 5 is a flow diagram of a method including generating an image from a received digital photograph according to one embodiment of the invention.

At block 502, a digital photograph (e.g., photograph 202 in FIG. 2) is received, wherein the photograph is provided by a user. At block 504, an image (e.g., image 204 in FIG. 2) is generated from the received digital photograph, wherein the generated image is to be printed on a film for application to a figurine to customize the figurine. At block 506, the image is provided for printing on the film for application to the figurine.

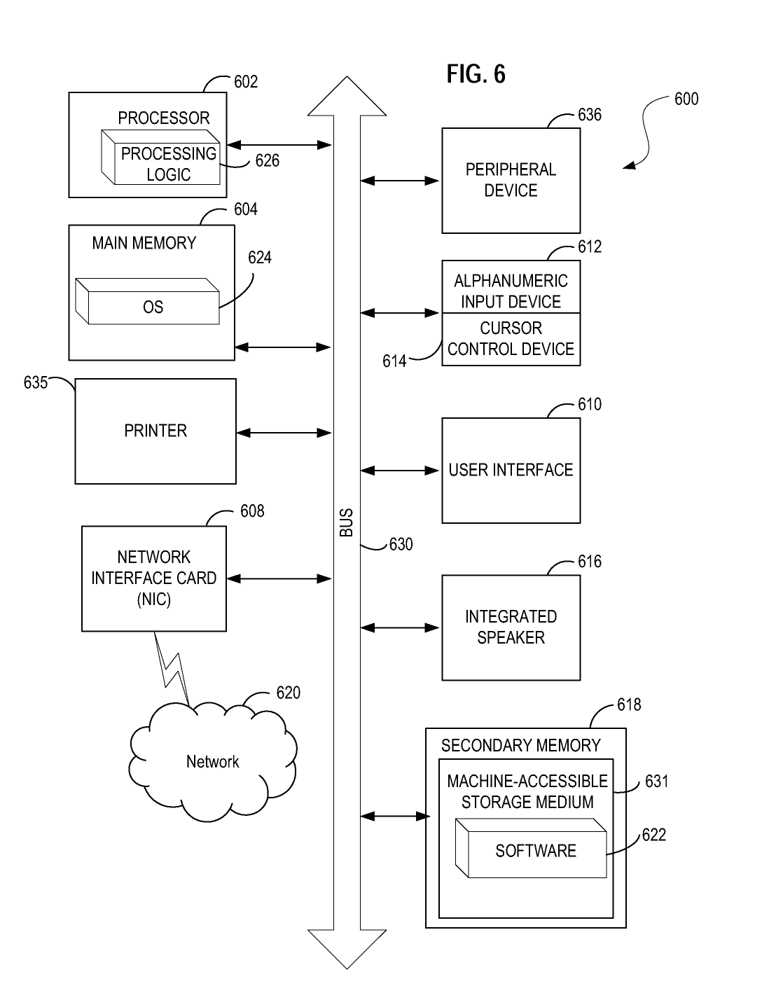

FIG. 6 is a block diagram of a machine 600 in the exemplary form of a computer system, in accordance with one embodiment, within which a set of instructions, for causing the machine/computer system 600 to perform any one or more of the methodologies discussed herein (e.g., the operations described with reference to FIG. 5), may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, as a peer machine in a peer-to-peer (or distributed) network environment, as a server or series of servers within an on-demand service environment. Certain embodiments of the machine may be in the form of a personal computer (PC), a tablet PC, a set-top box (STB), a Personal Digital Assistant (PDA), a cellular telephone, a web appliance, a server, a network router, switch or bridge, computing system, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein.

The exemplary computer system 600 includes a processor 602, a main memory 604 (e.g., read-only memory (ROM), flash memory, dynamic random access memory (DRAM) such as synchronous DRAM (SDRAM) or Rambus DRAM (RDRAM), etc., static memory such as flash memory, static random access memory (SRAM), volatile but high-data rate RAM, etc.), and a secondary memory 618 (e.g., a persistent storage device including hard disk drives), which communicate with each other via a bus 630. Main memory 604 includes an operating system (OS) 624. According to one embodiment, main memory 604 and OS 624 operate in conjunction with processing logic 626 and processor 602 to perform the methodologies discussed herein.

Processor 602 represents one or more general-purpose processing devices such as a microprocessor, central processing unit, or the like. Processor 602 may also be one or more special-purpose processing devices such as an application specific integrated circuit (ASIC), a field programmable gate array (FPGA), a digital signal processor (DSP), graphics processor, or the like. Processor 602 is configured to execute the processing logic 626 for performing the operations and functionality which is discussed herein.

The computer system 600 may further include a network interface card 608. The computer system 600 also may include a user interface 610 (such as a video display unit, a liquid crystal display (LCD), or a cathode ray tube (CRT), an alphanumeric input device 612 (e.g., a keyboard), a cursor control device 614 (e.g., a mouse), and a signal generation device 616 (e.g., an integrated speaker). The computer system 600 may further include printer 635 (e.g., a laser printer) and peripheral device 636 (e.g., wireless or wired communication devices, memory devices, storage devices, audio processing devices, video processing devices, etc.).

The secondary memory 618 may include a non-transitory machine-readable or computer readable storage medium 631 on which is stored one or more sets of instructions (e.g., software 622) embodying any one or more of the methodologies or functions described herein. The software 622 may also reside, completely or at least partially, within the main memory 604 and/or within the processor 602 during execution thereof by the computer system 600, the main memory 604 and the processor 602 also constituting machine-readable storage media. The software 622 may further be transmitted or received over a network 620 via the network interface card 608.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific embodiments disclosed in the specification. Rather, the scope of the invention is to be determined entirely by the following claims, which are to be construed in accordance with established doctrines of claim interpretation.

What is claimed is:

1. A method of providing a customizable figurine, the method comprising:
providing a figurine;
providing a film for application to a surface of the figurine, wherein the film is to receive an image from a digital photograph provided by a user;
wherein the figurine is customizable by applying the film with the image from the digital photograph provided by the user to the surface of the figurine.

2. The method of claim 1, wherein:
the image to be received by the film includes a feature of a person from the digital photograph provided by the user; and
wherein the figurine that is customizable by applying the film to the surface of the figurine is customizable by
applying the film with the image including the feature of the person from the digital photograph to a portion of the figurine corresponding to the feature of the person.

3. The method of claim 2, wherein:
the feature of the person from the digital photograph in the image is desaturated and contrasted.

4. The method of claim 2, wherein:
the feature of the person from the digital photograph included in the image is a facial feature; and
wherein the figurine that is customizable by applying the film to the surface of the figurine is customizable by
applying, to a head of the figurine, the film onto which the image including the facial feature is to be applied.

5. The method of claim 1, wherein:
the film to receive the image is a sticker with an adhesive side for adhering to the surface of the figurine.

6. The method of claim 1, wherein:
the provided figurine comprises a model of a head which is removably attachable to a plurality of figurine bodies;
the model of the head comprises the surface onto which the film is applied; and the figurine is customizable by:
applying the film with the image to the surface of the model of the head, and
attaching the model of the head with the film applied to one of the plurality of figurine bodies.

7. The method of claim 1, wherein:
the figurine that is customizable by applying the film with the image from the digital photograph provided by the user to the surface of the figurine is customizable by:
removably applying the film with the image from the digital photograph provided by the user to the surface of the figurine.

8. An article of manufacture comprising a machine-readable storage medium having content stored thereon, which when executed causes a machine to perform operations including:
receiving a digital photograph provided by a user;
generating an image from the received digital photograph, wherein the generated image is to be printed on a film for application to a figurine to customize the figurine; and
providing the image for printing on the film for application to the figurine.

9. The article of manufacture of claim 8, wherein generating the image from the received digital photograph comprises:
sizing the image to print on the film for application to the figurine to customize the figurine.

10. The article of manufacture of claim 8, wherein generating the image from the received digital photograph comprises:
extracting a feature of a person from the received digital photograph, wherein
the generated image with the extracted feature of the person is to be printed on the film, and
the film onto which the image with the extracted feature of the person is to be printed is to be applied to a corresponding feature of the figurine to customize the figurine.

11. The article of manufacture of claim 10, wherein generating the image from the received digital photograph further comprises:
desaturating and increasing contrast of the image with the extracted feature of the person that is to be applied to the corresponding feature of the figurine to customize the figurine.

12. The article of manufacture of claim 8, wherein:
the extracted feature of a person from the received photograph is a facial feature; and
the film onto which the image with the extracted facial feature is to be printed is to be applied to a facial area of the figurine to customize the figurine.

13. The article of manufacture of claim 8, wherein:
the film onto which the provided image is to be printed is a sticker with an adhesive side for adhering to a surface of the figurine.

14. The article of manufacture of claim 8, wherein:
providing the image for printing on the film for application to the figurine comprises:
providing the image for printing on the film for application to a model of a head removably attachable to a plurality of figurine bodies; and
wherein the figurine that is customizable by applying the film with the image from the digital photograph provided by the user to the surface of the figurine is customizable by:
applying the film with the image to the model of the head and removably attaching the model of the head with the film to one of the plurality of figurine bodies.

15. The article of manufacture of claim 8, wherein:
the figurine that is customizable by applying the film to the surface of the figurine is customizable by:
removably applying the film with the image from the digital photograph provided by the user to the surface of the figurine.

16. A system comprising:
a figurine having a surface to receive an image to personalize the figurine;
a means for generating the image to personalize the figurine from a digital photograph provided by a user and sizing the image for application to the surface of the figurine; and
a means for applying the image to personalize the figurine to the surface of the figurine.

17. The system of claim 16, further comprising:
a means for printing the image for applying to the surface of the figurine to personalize the figurine.

18. The system of claim 16, wherein:
the image to be received by the surface of the figurine to personalize the figurine includes a facial feature; and
the means for sizing the image for application to the surface of the figurine comprise a means for sizing the image for application to a model of a head of the figurine.

19. The system of claim 16, wherein:
the means for applying the image to personalize the figurine to the surface of the figurine comprise an adhesive.

20. The system of claim 16, wherein:
the means for generating the image to personalize the figurine from the digital photograph provided by the user and sizing the image for application to the surface of the figurine comprise:
an article of manufacture comprising a machine-readable storage medium having content stored thereon, which when executed causes a machine to perform operations including:
receiving the digital photograph provided by the user;
generating the image to personalize the figurine from the received digital photograph; and
providing the image for printing on a film for application to the surface of the figurine.
